(19) United States
(12) Patent Application Publication
(10) Pub. No.: US 2025/0331069 A1
(43) Pub. Date: Oct. 23, 2025

(54) CERAMIC HEATER

(71) Applicant: MiCo Ceramics Ltd., Anseong-si (KR)

(72) Inventors: Jung-Chul Jin, Anseong-si (KR); Donggeun Seong, Anseong-si (KR); Jonggwan Park, Anseong-si (KR); Yubin Lee, Anseong-si (KR)

(21) Appl. No.: 19/172,744

(22) Filed: Apr. 8, 2025

(30) Foreign Application Priority Data
Apr. 22, 2024 (KR) 10-2024-0053354

(51) Int. Cl. H05B 3/28; H05B 3/00; H05B 3/03; H05B 3/08; H05B 3/18

(52) U.S. Cl. CPC H05B 3/283; H05B 3/0019; H05B 3/0047; H05B 3/03; H05B 3/08; H05B 3/18; H05B 2203/003; H05B 2203/014

(57) ABSTRACT

Provided is a ceramic heater. The ceramic heater includes a disk-shaped plate and a heating element embedded in the plate. A portion of the heating element is a coiled wire, and another portion of the heating element is a non-coiled wire. The non-coiled wire is arranged in a central portion of the plate.

### CROSS-REFERENCE TO RELATED APPLICATION(S)

This application is based on and claims priority under 35 U.S.C. 119 to Korean Patent Application No. 10-2024-0053354, filed on Apr. 22, 2024, in the Korean Intellectual Property Office, the disclosure of which is herein incorporated by reference in its entirety.

### BACKGROUND OF THE INVENTION

### 1. Field of the Invention

The present disclosure relates to a ceramic heater, and more specifically, to a ceramic heater capable of reducing variations in the amount of heat generated depending on the position of a ceramic plate by modifying the structure of a heating element.

### 2. Description of the Prior Art

In general, in order to manufacture a flat display panel or a semiconductor device, substrates such as a glass substrate, a flexible substrate, or a semiconductor substrate are subjected to processes of sequentially laminating and patterning a series of layers including a dielectric layer and a metal layer thereon. In this case, the series of layers such as the dielectric layer and the metal layer are deposited on a substrate through a process such as chemical vapor deposition (CVD) or physical vapor deposition (PVD).

In order to uniformly form these layers, the substrate should be heated to a uniform temperature, and a ceramic heater as a substrate heating device may be used to heat and support the substrate. The substrate heating device is used for heating a substrate during a deposition process for depositing a thin film layer on the substrate, an etching process for etching a dielectric or metal layer on the substrate, a firing process for firing a photoresist, or the like. Recently, there has been a continued demand for a method for reducing the temperature variations of ceramic heaters due to the miniaturization of semiconductor device wiring and the need for precise heat treatment of semiconductor substrates.

FIG. 1 is a view illustrating a conventional ceramic plate with a built-in heating element.

In general, a ceramic heater includes a ceramic plate 1 with a built-in heating element 2 and a shaft that supports the ceramic plate 1. In a conventional ceramic plate 1 using a coil-shaped heating element 2, the heating element 2 may not be arranged or densely arranged in the central portion C of the ceramic plate 1 where the shaft is connected. As a result, there is a problem in that the temperature of the central portion of the ceramic plate may not be quickly increased, or a cool zone may occur in the central portion. In addition, there is a problem in that heat is released through a shaft joint adjacent to the central portion C. These problems frequently occur in heaters for high temperatures exceeding 550° C. and lead to reduced temperature uniformity of the ceramic heater.

When the density of the coil-shaped heating element 2 is increased to compensate for the heat loss in the cool zone, cracks may form in the ceramic plate 1 due to thermal stress. In addition, in the case of a two-zone heating element where the heating element 2 is arranged in an inner zone 3 and an outer zone 4 of the ceramic plate 1, the temperature of an intermediate area of the ceramic plate 1 increases due to the thermal overlap between the inner and outer peripheral heating elements.

When a temperature variation occurs at each area of the ceramic plate 1 as described above, a thin film may not be formed uniformly on the substrate, and the durability of the ceramic plate 1 may deteriorate.

### SUMMARY OF THE INVENTION

The present disclosure aims to reduce a temperature variation at each position of a ceramic plate.

In addition, the present disclosure aims to increase the amount of heat generated in the central portion of a ceramic plate.

Furthermore, the present disclosure aims to prevent a localized temperature increase in a ceramic plate caused by thermal overlap.

An embodiment of the present disclosure provides a ceramic heater including a plate and a heating element embedded in the plate. A portion of the heating element is a coiled wire, and another portion of the heating element is a non-coiled wire. The non-coiled wire is arranged in a central portion of the plate.

An embodiment of the present disclosure provides the ceramic heater, in which the heating element includes an outer peripheral heating element located in an outer peripheral area of the plate and an inner peripheral heating element located in an inner peripheral area of the plate. The outer peripheral heating element is a coiled wire heating element, at least a portion of the inner peripheral heating element is arranged in the central portion of the plate, and the inner peripheral heating element arranged in the central portion is a non-coiled wire.

An embodiment of the present disclosure provides the ceramic heater, in which the ceramic heater includes a cylindrical shaft having an internal space. The plate includes a first surface and a second surface, the shaft is connected to the second surface of the plate, the central portion of the plate corresponds to the internal space of the shaft, and the inner peripheral non-coiled wire heating element is arranged in the central portion of the plate corresponding to the internal space of the shaft.

An embodiment of the present disclosure provides a ceramic heater, in which the inner peripheral heating element arranged in the central portion of the plate is located on a first plane, the inner peripheral heating element arranged outside the central portion of the plate is located on a second plane, and the first plane and the second plane are spaced apart from each other in the thickness direction of the plate.

An embodiment of the present disclosure provides the ceramic heater, in which the plate includes a columnar electrode extending in the thickness direction of the plate, the electrode includes a first end portion and a second end portion formed in the thickness direction of the plate, the inner peripheral heating element arranged in the central portion of the plate is connected to the first end portion of the electrode, and the inner peripheral heating element arranged outside the central portion of the plate is connected to the second end portion of the electrode.

An embodiment of the present disclosure provides the ceramic heater, in which the inner peripheral heating element arranged in the central portion of the plate and the inner peripheral heating element arranged outside the central portion of the plate are located on the same plane.

An embodiment of the present disclosure provides the ceramic heater, in which the inner peripheral heating element arranged in the central portion of the plate and the inner peripheral heating element arranged outside the central portion of the plate have different wire diameters or materials.

An embodiment of the present disclosure provides the ceramic heater, in which the inner peripheral heating element arranged in the central portion of the plate and the inner peripheral heating element arranged outside the central portion of the plate are electrically connected by a conductive connecting member.

An embodiment of the present disclosure provides the ceramic heater, in which the inner peripheral heating element is electrically connected to a pair of first terminals, and the outer peripheral heating element is electrically connected to a pair of second terminals.

An embodiment of the present disclosure provides the ceramic heater, in which the inner peripheral heating element arranged in the central portion of the plate is provided in a pattern of a line symmetry shape.

An embodiment of the present disclosure provides a ceramic heater including a plate and a heating element embedded in the plate. The heating element includes multiple concentric arc portions and multiple connecting portions connecting the concentric arc portions. The concentric arc portions include a first arc portion closest to a center of the plate and a second arc portion farthest from the center of the plate. At least one arc portion between the first arc portion and the second arc portion is a non-coiled wire, and an arc portion, other than the non-coiled wire arc portion, between the first arc portion and the second arc portion is a coiled wire.

An embodiment of the present disclosure provides the ceramic heater, in which, when a distance between the second arc portion and the center of the plate is divided into three equal portions, the non-coiled wire arc portion is located in a middle area of the distance divided into the three equal portions.

An embodiment of the present disclosure provides the ceramic heater, in which the heating element is electrically connected to a pair of first terminals.

An embodiment of the present disclosure provides the ceramic heater, in which the first arc portion is electrically connected to a pair of first terminals, and the second arc portion is electrically connected to a pair of second terminals.

An embodiment of the present disclosure provides the ceramic heater, in which the non-coiled wire and the coiled wire have different wire diameters or materials.

An embodiment of the present disclosure provides the ceramic heater, in which the non-coiled wire and the coiled wire are connected by a conductive connecting member.

An embodiment of the present disclosure provides the ceramic heater, in which the heating element includes an outer peripheral heating element located in an outer peripheral area of the plate and an inner peripheral heating element located in an inner peripheral area of the plate.

An embodiment of the present disclosure provides the ceramic heater, in which the heating element further includes a non-coiled heating pattern arranged in the central portion of the plate.

According to an embodiment of the present disclosure, it is possible to increase the amount of heat generated in the central portion of the ceramic plate, thereby accelerating the temperature increase rate in the central portion and preventing a low-temperature area from being generated in the central portion.

In addition, by preventing thermal overlap from occurring in the ceramic plate, it is possible to reduce a temperature variation at each position of the ceramic plate.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a view illustrating a conventional ceramic plate with a built-in heating element;

FIG. 2 is a perspective view of a ceramic heater according to an embodiment of the present disclosure;

FIG. 3 is a plan view schematically illustrating the embedded state of a heating element embedded in a ceramic plate according to an embodiment of the present disclosure;

FIG. 4 is an enlarged view of portion A in FIG. 3;

FIG. 5 is a view illustrating the shape of the heating element of FIG. 4 according to an embodiment of the present disclosure;

FIG. 6 is an enlarged view of portion B in FIG. 4;

FIG. 7 is a diagram illustrating the temperature trends of a ceramic plate according to an embodiment of the present disclosure and a conventional ceramic plate;

FIGS. 8A and 8B are diagrams illustrating the temperature at each position of a ceramic plate according to an embodiment of the present disclosure and a conventional ceramic plate;

FIGS. 9A and 9B are diagrams illustrating the heat generation state at each area of a ceramic plate according to an embodiment of the present disclosure and a conventional ceramic plate;

FIGS. 10A and 10B are views illustrating the shape of a heating element according to another embodiment of the present disclosure;

FIG. 11 is an enlarged view of portion C in FIG. 10B;

FIG. 12 is a view illustrating the shape of a heating element according to yet another embodiment of the present disclosure;

FIG. 13 is an enlarged view of portion D in FIG. 12;

FIGS. 14A and 14B are views illustrating intervals in the heating element according to another embodiment of the present disclosure and a conventional heating element;

FIG. 15 is an enlarged view of portion E in FIG. 12; and

FIG. 16 is a view illustrating a modification of the heating element shape illustrated in FIG. 12.

### DETAILED DESCRIPTION OF THE EXEMPLARY EMBODIMENTS

Hereinafter, embodiments disclosed herein will be described in detail with reference to the accompanying drawings. Regardless of drawing numbers, the same or similar elements will be assigned the same reference numerals, and redundant descriptions thereof will be omitted. In the following description of embodiments of the present disclosure, when each layer (film), area, pattern, or structure is described as being formed “above/on” or “below/under” a substrate, each layer (film), area, pad or patterns, the terms “above/on” and “below/under” are used to cover being formed either “directly” or “indirectly via another layer”. In addition, the criterion for above/on or below/above for each layer will be described with reference to the drawings. In the drawings, the thickness or size of each layer is exaggerated, omitted, or schematically illustrated for convenience and clarity of description. In addition, the size of each component does not fully reflect the actual size.

As used herein, expressions such as “including”, “comprising”, or “consisting of” are intended to indicate any features, numbers, steps, operations, elements, or some or combinations thereof, and should not be construed to exclude the existence or possibility of one or more other features, numbers, steps, operations, elements, or some or combinations thereof, in addition to those described above.

In addition, terms such as “first” and “second” may be used to describe various components, but the components are not limited by the terms, and these terms are only used for the purpose of distinguishing one component from another.

In addition, in describing the embodiments disclosed herein, when it is determined that detailed descriptions of related known technologies may obscure the gist of the embodiments disclosed herein, the detailed descriptions will be omitted.

It should be understood that the accompanying drawings are only for easy understanding of the embodiments disclosed herein, and that the technical idea disclosed herein is not limited by the accompanying drawings, and includes all changes, equivalents, and substitutes included in the spirit and technical scope of the present disclosure.

Hereinafter, various embodiments of the present disclosure will be described in detail with reference to the drawings.

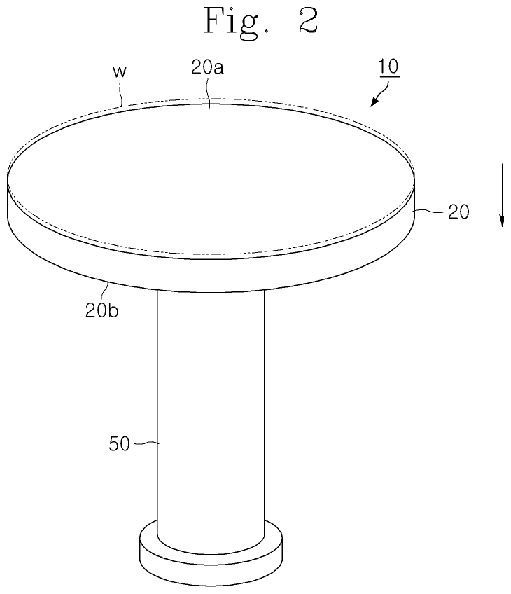

FIG. 2 is a perspective view of a ceramic heater according to an embodiment of the present disclosure.

The ceramic heater 10 is a device that supports heat treatment objects for various purposes, such as semiconductor wafers, glass substrates, and flexible substrates, and heats the heat treatment objects to a predetermined temperature.

The ceramic heater 10 includes a plate 20 on which a heat treatment object, such as a semiconductor wafer W, is mounted, and a cylindrical shaft 50 coupled to a bottom surface 20b of the plate. The plate 20 has a flat mounting surface (first surface) 20a on which the heat treatment object is mounted, and a bottom surface (second surface) 20b on which the shaft 50 is coupled on the opposite side of the mounting surface.

The plate 20 is a disk-shaped plate including a ceramic material such as aluminum nitride or alumina, with a heating element arranged inside the plate for heating the heat treatment target. The diameter of the ceramic plate 20 is, for example, about 300 mm. The shaft 50 may be made of ceramic, such as aluminum nitride or alumina, similar to the plate 20. The shaft 50 is formed in a cylindrical shape with an internal space and includes, inside the internal space, a rod configured to supply current to the heating element.

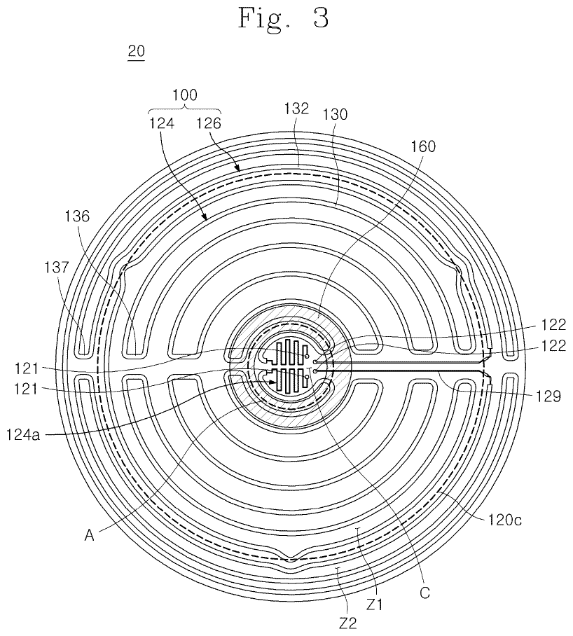

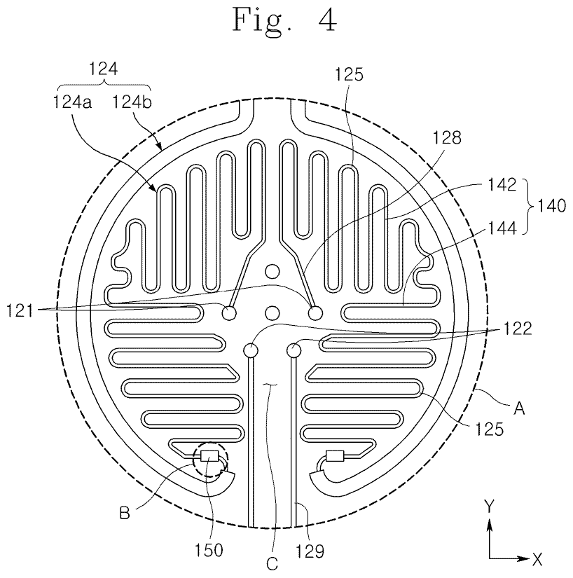

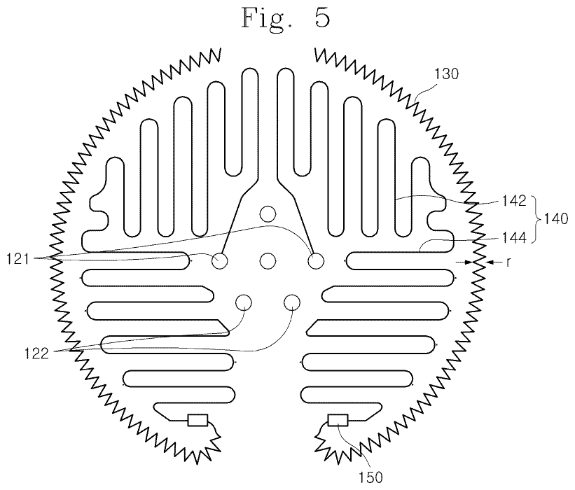

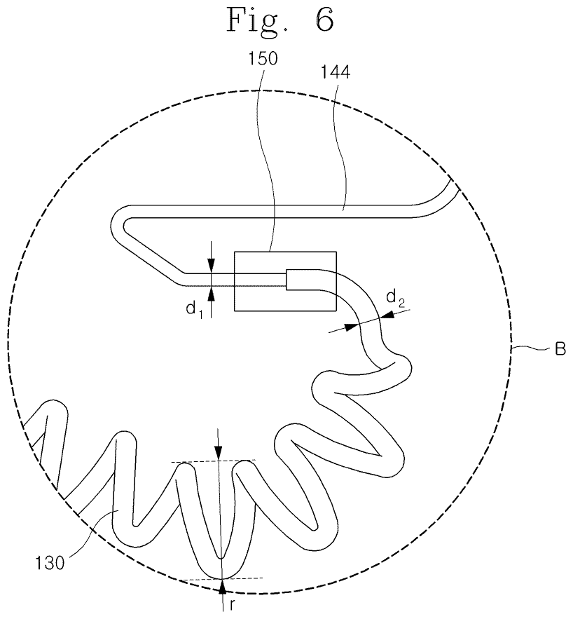

FIG. 3 is a plan view schematically illustrating the embedded state of a heating element embedded in a ceramic plate according to an embodiment of the present disclosure. FIG. 4 is an enlarged view of portion A in FIG. 3. FIG. 5 is a view illustrating the shape of the heating element of FIG. 4 according to an embodiment of the present disclosure. FIG. 6 is an enlarged view of portion B in FIG. 4.

Referring to FIGS. 3 to 6, the heating element 100 may be embedded in the plate 20 corresponding to the position of a heat treatment object. The heating element 100 may be embedded in the plate 20 parallel to the mounting surface 20a of the plate, allowing it to control the heating temperature uniformly based on its position to uniformly heat the heat treatment object as a whole by heat generation, and allowing the distance at which heat is transferred to the heat treatment object to be maintained constant at nearly all positions.

The heating element 100 may have a shape that corresponds to the shape of the heat treatment object. The heating element 100 may be formed in a concentric circular shape or a flat plate shape using a heating wire or a resistance wire. The heating element 100 may include at least one compound selected from the group consisting of tungsten (W), molybdenum (Mo), molybdenum carbide such as Mo₂C, MoC, or Mo₃C₂, tungsten carbide, silver (Ag), gold (Au), platinum (Pt), niobium (Nb), and titanium (Ti), or an alloy of the compound or a composite containing the compound. The heating element 100 may be electrically connected to terminals 121 and 122 via lead wires 128 and 129.

In an embodiment of the present disclosure, the heating element 100 may be configured with two or more heating elements to heat several divided zones. For example, FIG. 3 illustrates the heating element 100 configured with an inner peripheral heating element 124 and an outer peripheral heating element 126 for heating respective zones, by dividing the plate into an inner peripheral zone Z1 and an outer peripheral zone Z2. Hereinafter, a ceramic heater 10, in which the plate is divided into the inner peripheral zone Z1 and the outer peripheral zone Z2, will be described as an example, but the present disclosure is not limited thereto. For example, the plate 20 of the ceramic heater may have a heating element in a single zone without dividing the plate into multiple zones. Alternatively, the present disclosure may also be applied to a multi-zone heater that is divided into multiple fan-shaped areas at a predetermined angle and has heating elements corresponding to the respective divided areas.

Based on a concentric virtual boundary 120c of the ceramic plate 20, the ceramic plate 20 is divided into an inner peripheral zone Z1, which is the inner peripheral area inside the virtual boundary 120c, and an outer peripheral zone Z2, which is the outer peripheral area outside the virtual boundary 120c. The diameter of the virtual boundary 120c is, for example, about 200 mm. In the inner peripheral zone Z1 of the ceramic plate 20, an inner peripheral heating element 124 is embedded, while in the outer peripheral zone Z2, an outer peripheral heating element 126 is embedded. The inner and outer peripheral heating elements 124 and 126 are embedded in the plate 20 on the same plane parallel to the wafer mounting surface 20a.

A pair of first terminals 121 and a pair of second terminals 122 may be provided near the central portion C of the circumference of the plate 20. The first terminals 121 connect a rod to the inner peripheral heating element 124 to supply current to the inner peripheral heating element 124 via the rod. The second terminals 122 connect a rod to the outer peripheral heating element 126 to supply current to the outer peripheral heating element 126 via the rod.

In an embodiment of the present disclosure, the outer peripheral heating element 126 is configured with a coiled wire, whereas the inner peripheral heating element 124 includes, in a portion, a non-coiled wire (a straight wire not wound helically or three-dimensionally). In this specification, a non-coiled wire refers to a wire that is not wound helically or three-dimensionally.

Specifically, the outer peripheral heating element 126 may be a coiled wire formed by helically winding a bare wire with a diameter of, for example, about 0.3 to about 0.6 mm, where the winding diameter r of the coil may range from about 2.0 to about 6.0 mm. A portion of the inner peripheral heating element 124 may be a coiled wire, while the other portion may be a non-coiled wire where a bare wire is not helically wound.

In an embodiment of the present disclosure, the inner peripheral heating element 124 is partially configured with a non-coiled wire to densely form the heating element in the central portion C of the plate. Preferably, the inner peripheral heating element 124 may be partially configured with a non-coiled wire in the central portion C of the circumference, which is the area including the center of the disk-shaped plate 20. The central portion C of the circumference may be an area with a radius extending a predetermined distance from the center of the disk-shaped plate 20.

A cylindrical shaft 50 is fixedly attached to the lower surface 20b of the plate, which is the surface opposite to the mounting surface 20a. In FIG. 3, reference numeral 160 indicates the area of the lower surface 20b to which the shaft 50 is attached. The shaft 50 is a cylindrical structure with an internal hollow space, where components such as rods are arranged. The central portion C of the circumference of the plate is an area corresponding to the internal space of the shaft 50, and may be an area where the plate 20 and the internal space of the shaft 50 overlap when viewed in the thickness direction T of the plate 20. The central portion C of the circumference may also be an area surrounded by the cylindrical shaft 50 when viewed in the thickness direction T of the plate 20.

In a conventional ceramic heater, it has been difficult to densely arrange a heating element 100 in the central portion C of the circumference of a ceramic plate, resulting in the formation of a cool zone. However, according to an embodiment of the present disclosure, by densely forming an inner peripheral heating element 124 with a non-coiled wire in the central portion C of the circumference, the amount of heat generated in the central portion C of the plate may be increased, thereby accelerating the heating rate of the center.

The inner peripheral heating element 124 and the outer peripheral heating element 126 will be described in detail below.

The inner peripheral heating element 124 starts from one first terminal 121, is continuously wired in the inner peripheral zone Z1 of the plate 20 to form a certain pattern such as a straight portion and/or a concentric arc portion, and is then connected to the remaining first terminal 121. The first terminals 121 and the inner peripheral heating element 124 may be connected by lead wires 128 in the form of a non-coiled wire.

Specifically, a first inner peripheral heating element 124a located in the central portion C of the circumference may be formed in a non-coiled heating pattern. The non-coiled heating pattern may include multiple straight portions 140 configured as a non-coiled wire heating element and first connecting portions 125 each connecting adjacent straight portions 140. The straight portions 140 may be formed in one direction, as illustrated in FIG. 3, or in multiple different directions, as illustrated in FIG. 4. FIG. 4 is an enlarged view of a portion A of FIG. 3, illustrating straight portions 140 of a shape different from those illustrated in FIG. 3.

Referring to FIG. 4, multiple first straight portions 142 may be formed in the Y-direction, which is parallel to the first surface 20a of the ceramic plate, and second straight portions 144, which continuously extend from the first straight portions 142, may be formed in the X-direction. The X-direction and Y-direction are parallel to the first surface 20a of the plate, and the X-direction is perpendicular to the Y-direction.

Specifically, the straight portions 142 connected to a pair of first terminals 121 via the lead wires 128 extend in the Y-direction and are bent at the first connecting portions 125 to curve into the X-direction. The straight portions 142 bent at the first connecting portions 125 extend in the Y-direction opposite to the previous direction and are bent again at the first connecting portions 125 to curve into the X-direction. By repeating this process, the semicircular area above the central portion C (based on the drawing) is wired as the straight portions 142 in the Y-direction.

The straight portions 144, which continuously extend from the straight portions 142 in the Y-direction, are wired in the X-direction. The straight portions 144 extend in the X-direction and are bent at the first connecting portions 125 to curve into the Y-direction. The straight portions 144 bent at the first connecting portions 125 extend in the X-direction opposite to the previous direction and are bent again at the first connecting portions 125 to curve into the X-direction. By repeating this process, the semicircular area below the central portion C is wired as the straight portions 144 in the X-direction. At this time, the straight portions 144 may be wired in areas other than the area where the lead wires 129 of the outer peripheral heating element are formed.

The straight portions 150 of the non-coiled heating pattern may be in the form of a straight line using non-coiled wires, as illustrated in the drawing, or in various shapes such as arc shapes, sine wave shapes, triangular wave shapes, or square wave shapes. In addition, the non-coiled heating pattern may be formed in a line symmetry with left-right symmetry as illustrated in FIG. 4, but the symmetrical shape is not limited thereto. Furthermore, due to internal structures such as lift pins installed inside the plate 20, the non-coiled heating pattern may also be formed in an asymmetrical structure rather than a symmetrical one.

A second inner peripheral heating element 124b located outside the central portion C of the circumference may continuously extend from the straight portions 144 in the X-direction. The second inner peripheral heating element 124b located outside the central portion C of the circumference may be wired using a coiled wire. The second inner peripheral heating element 124b includes multiple concentric arc portions 130 and second connecting portions 136 connecting the concentric arc portions 130. Specifically, the second inner peripheral heating element 124b may form multiple concentric patterns by being folded at multiple connecting portions 136.

The multiple concentric patterns of the second inner peripheral heating element 124b may include multiple concentric arc portions 130 that extend in the circumferential direction of the plate 20 (the direction along the circumference of a circle). In addition, the multiple concentric patterns may include multiple second connecting portions 136 that connects adjacent concentric arc portions 130 among the multiple concentric arc portions 130. The adjacent arc portions 130 may be connected by the second connecting portions 136 extending in the radial direction.

At this time, the first inner peripheral heating element 124a and the second inner peripheral heating element 124b may be arranged on the same plane. That is, the straight portions 140, the first connecting portions 125, the concentric arc portions 130, and the second connecting portions 136 may all be located on the same plane.

The outer peripheral heating element 126 starts from one second terminal 122, is continuously wired in the outer peripheral zone Z2, which is the outer peripheral area of the plate 20 to form a certain pattern such as concentric circles, and is then connected to the remaining second terminal 122. During this process, the outer peripheral heating element 126 may form multiple concentric patterns by being folded at third connecting portions 137 in a form that surrounds the inner peripheral heating element 124. The second terminals 122 and the outer peripheral heating element 126 may be connected by lead wires 129 in the form of a non-coiled wire.

Specifically, the multiple concentric patterns of the outer peripheral heating element 126 may include multiple concentric arc portions 132 that extend in the circumferential direction of the plate 20. In addition, the multiple concentric patterns may include third connecting portions 137 that connect adjacent arc portions 132 among the multiple concentric arc portions 132. Multiple third connecting portions 137 may be formed. The adjacent arc portions 132 may be connected by the third connecting portions 137 extending in the radial direction. Each of the concentric arc portions 130 and 132 of the second inner peripheral heating element 124b and the outer peripheral heating element 126 may have different diameters based on the center of the plate 20.

In an embodiment of the present disclosure, the inner peripheral heating element 124 and the outer peripheral heating element 126 may be formed using bare wires of the same diameter (wire diameter), or the heating element 100 may partially have different diameters. For example, the wire diameter d1 of the straight portions 140 of the first inner peripheral heating element and the wire diameter d2 of the concentric arc portions 130 of the second inner peripheral heating element may be made different. When the wire diameter d1 of the straight portions 140 is made smaller, the resistance increases, thereby increasing the amount of heat generated. In addition, the straight portions 140 may be made of a high-resistance alloy material such as MoW, while the remaining portions of the heating element may be made of Mo material to increase the amount of generated heat.

When the wire diameters or materials of the straight portions 140 and the concentric arc portions 130 are different, the straight portions 140 and the concentric arc portions 130 may be electrically connected by a conductive connecting member 150. For example, the straight portions 140 and the concentric arc portions 130 may be electrically connected using a connecting member disclosed in Korean Patent No. 10-2437076 in the name of the assignee of this application. The connecting member 150 may include an opening configured to secure wires with different diameters, such as those forming the straight portions 140 of the first inner peripheral heating element and the concentric arc portions 130, through interference fitting. The first inner peripheral heating element 124a including the straight portions 140, the second inner peripheral heating element 124b including the concentric arc portions 130, and the connecting member 150 may all be made of the same material, such as Mo, W, or MoW, or may be respectively made of different materials.

Without using the connecting member 150, the straight portions 140 and the concentric arc portions 130 may be configured as a single wire, and the connecting portion between the straight portions 140 and the concentric arc portions 130 may be made to have a tapering shape. Alternatively, the connecting portion between the straight portions 140 and the concentric arc portions 130 may be joined by welding or the like.

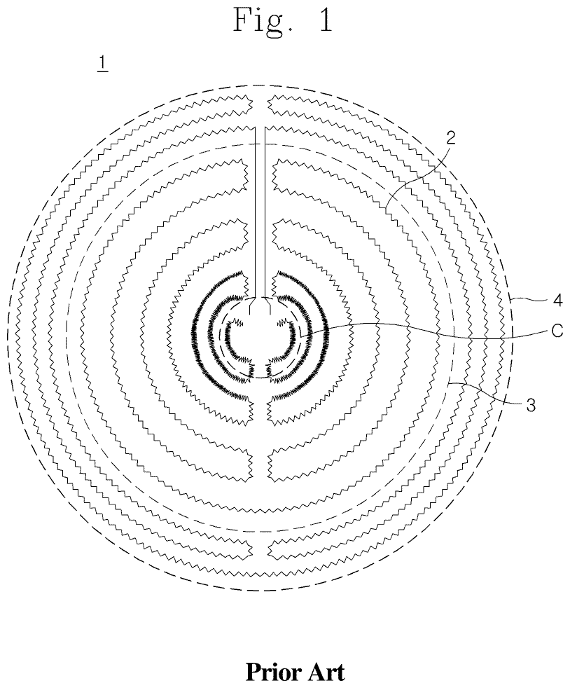

The amount of generated heat of the heating element for heating the plate to a predetermined temperature, for example, 450° C., may be calculated as electric energy. A comparison of the power energy between the conventional ceramic heater illustrated in FIG. 1 and the ceramic heater according to an embodiment of the present disclosure is as follows.

A heating element 2 made of Mo material and wired in the central portion C of a conventional ceramic plate had a wire diameter of 0.5 mm, a coil winding diameter of 3 mm, and a heating element length of about 573.0 mm, and the electric power energy was only about 55.3 W. In contrast, a ceramic plate 20 according to an embodiment of the present disclosure, having a heating element of the same material and wire diameter as the conventional one, had a length of about 1,061.4 mm for the inner peripheral heating element 124 with straight portion patterns arranged in the central portion C, and the electric power energy reached about 108.2 W. Furthermore, when the wire diameter of the straight portions 140 was 0.4 mm, the electric power energy reached 230.3 W, and when the wire diameter was 0.3 mm, the electric power energy reached 409.5 W.

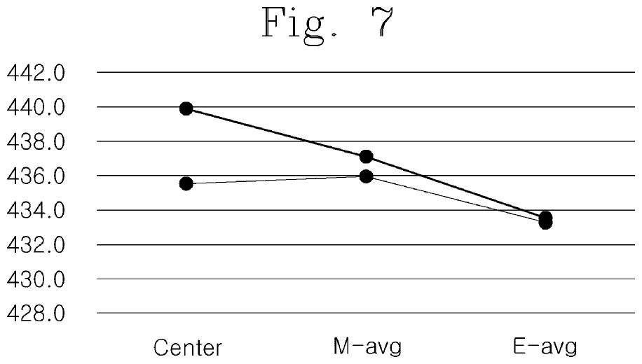

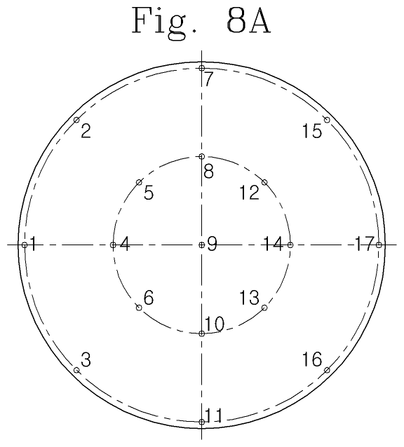

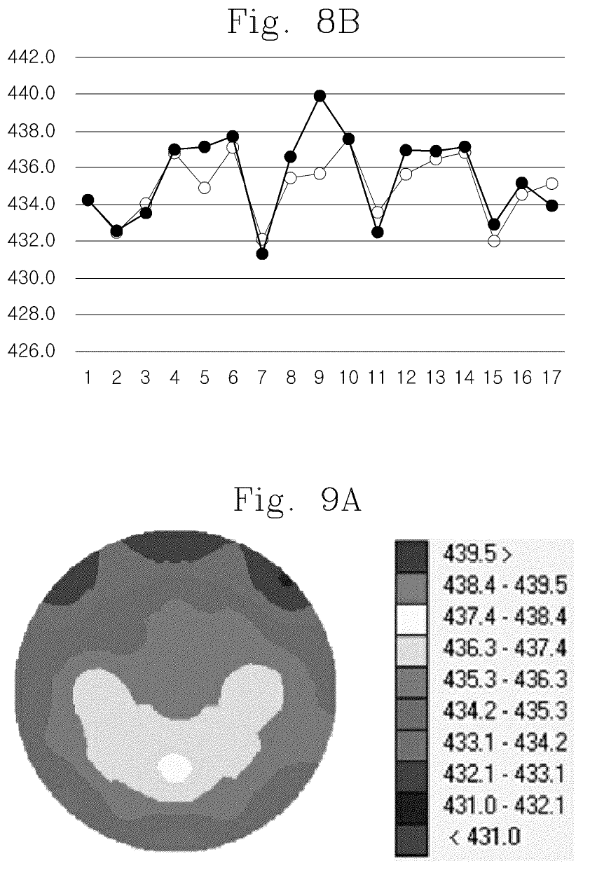

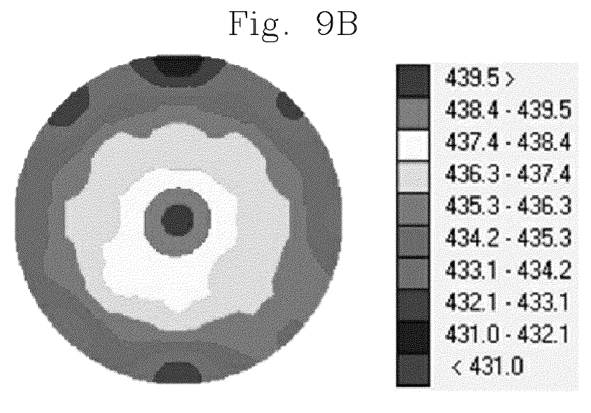

FIG. 7 is a diagram illustrating the temperature trends of a ceramic plate according to an embodiment of the present disclosure and a conventional ceramic plate. FIGS. 8A and 8B are diagrams illustrating the temperature at each position of a ceramic plate according to an embodiment of the present disclosure and a conventional ceramic plate. FIGS. 9A and 9B are diagrams illustrating the heat generation state at each area of a ceramic plate according to an embodiment of the present disclosure and a conventional ceramic plate.

In FIG. 7, the Y-axis represents the temperature (° C.), and the X-axis represents the position within the plate. “Center” represents the temperature at the central portion (position 9 in FIG. 8A), “M-avg” represents the average temperature in the middle area (positions 4, 5, 6, 8, 10, 12, 13, and 14 in FIG. 8A), and “E-avg” represents the average temperature in the outer area (positions 1, 2, 3, 7, 11, 15, 16, and 17 in FIG. 8A). In addition, the gray trendline (lower trendline) represents the temperature trend of the conventional ceramic plate, and the black trendline (upper trendline) represents the temperature trend of the ceramic plate according to an embodiment of the present disclosure. As shown in FIG. 7, according to an embodiment of the present disclosure, it can be observed that the temperature in the central portion (Center) increased.

FIG. 8A illustrates the positions of 17 points where the temperature of the ceramic plate was measured. FIG. 8B shows the temperatures measured at the 17 points, in which the Y-axis represents the temperature (° C.), the X-axis represents the numbers of the 17 points, the gray trendline indicates the temperature at each position of a conventional ceramic plate, and the black trendline indicates the temperature at each position of a ceramic plate according to an embodiment of the present disclosure. As shown in FIG. 8B, according to an embodiment of the present disclosure, the temperature increased in the central portion (points 4, 5, 6, 8, 9, 10, 12, 13, and 14).

FIG. 9A shows the temperature distribution of a conventional ceramic plate, and FIG. 9B shows the temperature distribution of a ceramic plate according to an embodiment of the present disclosure. As shown in FIG. 9B, it can be observed that the temperature of the central portion of the ceramic plate according to an embodiment of the present disclosure increased.

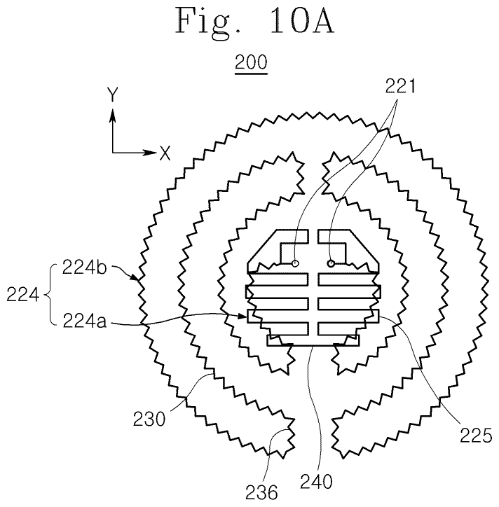

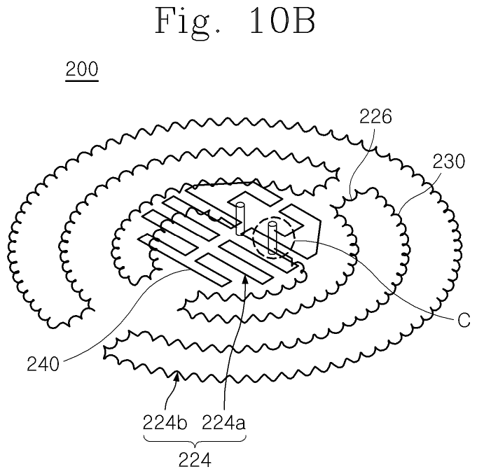

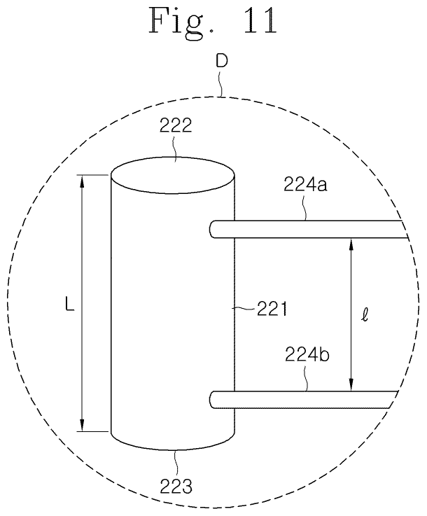

FIGS. 10A and 10B are views illustrating the shape of a heating element according to another embodiment of the present disclosure, and FIG. 11 is an enlarged view of portion C in FIG. 10B. FIG. 10A is a plan view of the heating element, and FIG. 10B is a perspective view of the heating element.

The following description refers to FIGS. 3, 10A, 10B, and 11. Among the components not illustrated in FIGS. 10A, 10B, and 11, components identical to those in FIG. 3 will be described with reference to FIG. 3. In addition, for components illustrated in FIG. 3 that are identical to those illustrated in FIGS. 10A, 10B, and 11, reference may be made to the description of FIG. 3.

A heating element 200 according to another embodiment of the present disclosure may also be formed by dividing the heating element into the inner peripheral zone Z1, which is the inner peripheral area inside the virtual boundary 120c, and the outer peripheral zone Z2, which is the outer peripheral area outside the virtual boundary 120c. The diameter of the virtual boundary 120c may be, for example, about 200 mm. The inner peripheral zone Z1 of the ceramic plate 20 is embedded with an inner peripheral heating element 224, while the outer peripheral zone Z2 is embedded with an outer peripheral heating element (not illustrated). The inner peripheral heating element 224 and the outer peripheral heating element are embedded in the plate 20 on the same plane parallel to the wafer mounting surface 20a. Although only the inner peripheral heating element 224 is illustrated in FIGS. 10A and 10B, the outer peripheral heating element may also be formed as in FIG. 3.

A pair of third terminals 221 and a pair of fourth terminals (not illustrated) may be provided near the central portion C of the circumference of the plate 20. The third terminals 221 connect a rod to the inner peripheral heating element 224 to supply current to the inner peripheral heating element 224 via the rod. The fourth terminals connect a rod to the outer peripheral heating element to supply current to the outer peripheral heating element via the rod.

The outer peripheral heating element is configured with a coiled wire, while a portion of the inner peripheral heating element 224 is configured with a non-coiled wire. Specifically, the outer peripheral heating element may be a coiled wire formed by helically winding a bare wire with a diameter of, for example, 0.3 to 0.6 mm, where the winding diameter r of the coil may range from 2.0 to 6.0 mm. A portion of the inner peripheral heating element 224 may be a coiled wire, while the other portion may be a non-coiled wire where a bare wire is not helically wound.

In an embodiment of the present disclosure, the inner peripheral heating element 124 is partially configured with a non-coiled wire to densely form the heating element in the central portion C of the plate. Preferably, the inner peripheral heating element 224 may be partially configured with a non-coiled wire in the central portion C of the circumference, which is the area including the center of the disk-shaped plate 20. The central portion C of the circumference may be an area with a radius extending a predetermined distance from the center of the disk-shaped plate 20.

A cylindrical shaft 50 is fixedly attached to the lower surface 20b of the plate, which is the surface opposite to the mounting surface 20a. The area of the lower surface 20b to which the shaft 50 is attached will be denoted by reference numeral 160 in FIG. 3. The central portion C of the circumference of the plate is an area corresponding to the internal space of the shaft 50, and may be an area where the plate 20 and the internal space of the shaft 50 overlap when viewed in the thickness direction T of the plate 20. The central portion C of the circumference may also be an area surrounded by the cylindrical shaft 50 when viewed in the thickness direction T of the plate 20.

In the conventional ceramic heater, since it is difficult to densely arrange a heating element in the central portion C of the circumference, a cool area is formed. However, according to another embodiment of the present disclosure, by densely forming an inner peripheral heating element 224 using a non-coiled wire in the circumferential central portion C, the amount of heat generated in the central portion C of the plate may be increased.

A third terminal 221 according to another embodiment of the present disclosure may have a columnar shape, for example, a cylindrical electrode 221. The electrode 221 may have a circular first end 222 and second end 223 and a cylindrical length L. The shapes of the first end 222 and second end 223 are not limited to circular and may include a semicircular shape, a rectangular shape, or the like. The electrode 221 has opposite end portions in its longitudinal direction. Specifically, the electrode has an upper end portion (first end portion) corresponding to the upper portion of the electrode 221 (based on the drawing) including the first end 222, and a lower end portion (second end portion) corresponding to the lower portion of the electrode 221 including the second end 223. The electrode 221 is inserted into the plate 20 such that its longitudinal direction aligns with the thickness direction T of the plate 20. Accordingly, the first end portion and the second end portion of the electrode 221 are arranged up and down in the thickness direction T of the plate.

The inner peripheral heating element 224 includes a third inner peripheral heating element 224a, which is formed in a non-coiled heating pattern, and a fourth inner peripheral heating element 224b, which includes concentric arc portions 230. In this case, the third inner peripheral heating element 224a is connected to the first end portion, which is the upper end portion near the first end 222 of the electrode, and the fourth inner peripheral heating element 224b is connected to the second end portion, which is the lower end portion near the second end 223 of the electrode. Thus, the third inner peripheral heating element 224a and the fourth inner peripheral heating element 224b are spaced apart by a predetermined distance 1 in the thickness direction T of the plate 20 and are positioned on different planes. The third inner peripheral heating element 224a and the outer peripheral heating element may be located on the same plane or on different planes.

The third inner peripheral heating element 224a may be formed in a non-coiled heating pattern. The non-coiled heating pattern may include multiple straight portions 240 configured as a non-coiled wire heating element and fourth connecting portions 225 each connecting adjacent straight portions 240. The third inner peripheral heating element 224a starts from the first end portion of one electrode 221, is continuously wired to form a predetermined pattern including straight lines, and is then connected to the first end portion of the remaining electrode 221. The electrode 221 and the third inner peripheral heating element 224a may be connected by lead wires in the form of a non-coiled wire. The concentric arc portions 230 of the fourth inner peripheral heating element 224b start from the second end portion of one electrode 221, are continuously wired to form a predetermined pattern including concentric arcs, and are then connected to the second end portion of the remaining electrode 221. The electrodes 221 and the fourth inner peripheral heating element 224b may be connected by lead wires in the form of a non-coiled wire.

Specifically, the third inner peripheral heating element 224a located in the central portion C of the circumference may be formed in a straight-line pattern. Multiple straight portions 240 configured with a non-coiled wire are formed, and adjacent straight portions 240 are connected by fourth connecting portions 225. The straight portions 240 may be formed in one direction or in multiple different directions. For example, multiple straight portions 240 may be formed in the X-direction parallel to the first surface 20a of the ceramic plate, and additional straight portions continuously extending from these straight portions 240 may be formed in the Y-direction. The X-direction and Y-direction are parallel to the first surface 20a of the plate, and the X-direction is perpendicular to the Y-direction.

Referring to FIGS. 10A and 10B, the straight portions 240 connected to a pair of electrodes 221 extend in the X-direction and are bent into the Y-direction at the fourth connecting portions 225. The straight portions 240 bent at the fourth connecting portions 225 extend in the X-direction opposite to the previous direction and are bent again into the X-direction at the fourth connecting portions 225. By repeating this process, the area of the central portion C is wired with the straight portions 240. At this time, the straight portions 240 and the fourth connecting portions 225 may be formed on the same plane parallel to the first surface 20a of the plate.

The straight portions 240 of the non-coiled heating pattern may be in the form of a straight line using non-coiled wires, as illustrated in the drawing, or in various shapes such as arc shapes, sine wave shapes, triangular wave shapes, or square wave shapes. In addition, the non-coiled heating pattern may be formed in a line symmetry with left-right symmetry as illustrated in FIG. 10A, but the symmetrical shape is not limited thereto.

The fourth inner peripheral heating element 224b located outside the central portion C of the circumference may be configured with a coiled wire. The fourth inner peripheral heating element 224b includes multiple concentric arc portions 230 and fifth connecting portions 226 connecting the concentric arc portions 230. Specifically, the fourth inner peripheral heating element 224b may form multiple concentric patterns by being folded at multiple fifth connecting portions 226.

The multiple concentric patterns of the fourth inner peripheral heating element 224b may include multiple concentric arc portions 230 that extend in the circumferential direction of the plate 20. In addition, the multiple concentric patterns may include multiple fifth connecting portions 226 that connect adjacent concentric arc portions 230 among the multiple concentric arc portions 230. The adjacent arc portions 230 may be connected by the fifth connecting portions 226 extending in the radial direction. At this time, the concentric arc portions 230 and the fifth connecting portions 226 may be formed on the same plane parallel to the first surface 20a of the plate.

The plane (first plane) where the straight portions 240 and the fourth connecting portions 225 are formed and the plane (second plane) where the concentric arc portions 230 and the fifth connecting portions 226 are formed are different planes and spaced apart by a predetermined distance from each other in the thickness direction of the plate 20.

The straight portions 240 and the concentric arc portions 230 may be formed using bare wires of the same diameter (wire diameter) or using bare wires of different diameters. For example, the wire diameter of the straight portions 240 may be made smaller than that of the concentric arc portions 230 to increase the amount of heat generated in the central portion C. In addition, the straight portions 240 may be made of a high-resistance alloy material such as MoW, while the remaining portions of the heating element may be made of Mo material to increase the amount of generated heat.

When the wire diameters or materials of the straight portions 240 and the concentric arc portions 230 are different, the straight portions 240 and the concentric arc portions 230 may be electrically connected by a conductive connecting member 150, as described above. The third inner peripheral heating element 224a including the straight portions 240, the fourth inner peripheral heating element 224b including the concentric arc portions 230, and the connecting member 150 may all be made of the same material, such as Mo, W, or MoW, or may be respectively made of different materials.

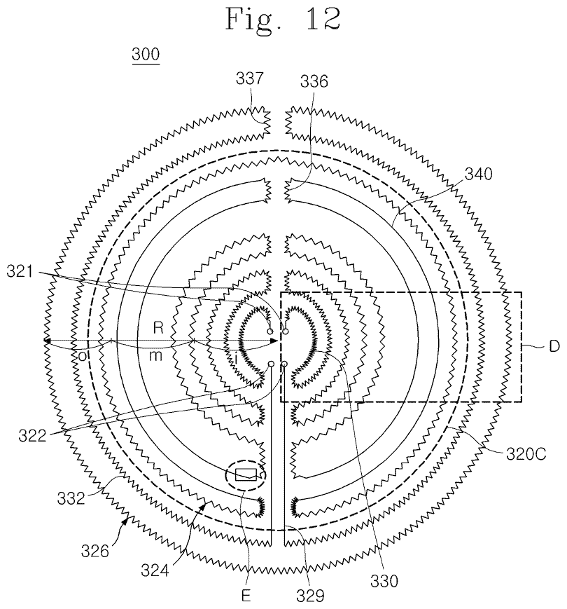

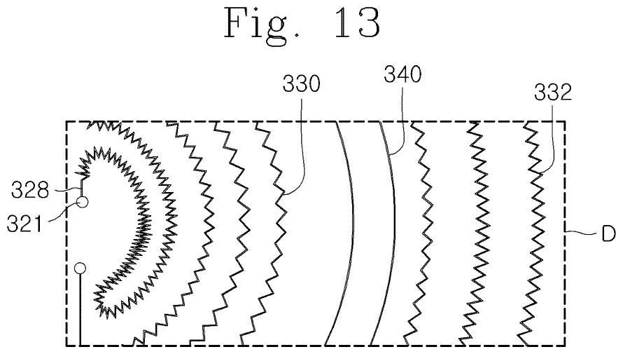

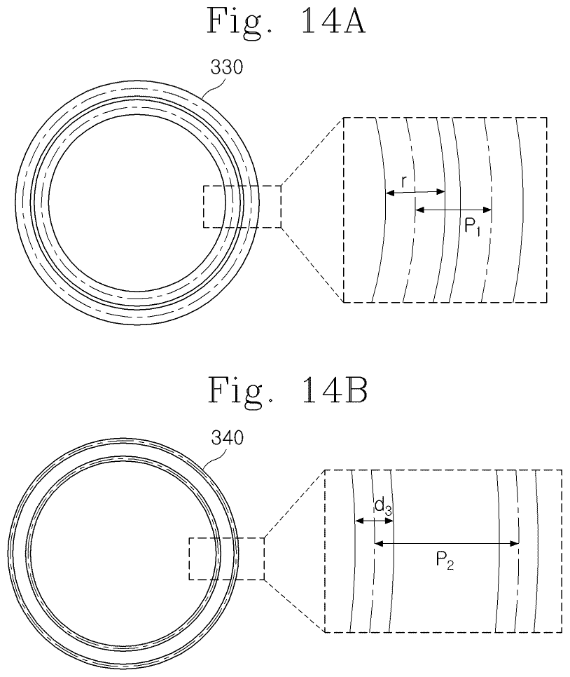

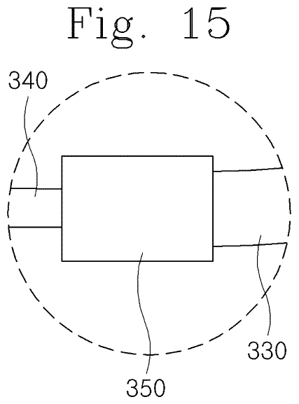

FIG. 12 is a view illustrating the shape of a heating element according to yet another embodiment of the present disclosure, and FIG. 13 is an enlarged view of portion D in FIG. 12. FIGS. 14A and 14B are views illustrating intervals in the heating element according to another embodiment of the present disclosure and a conventional heating element. FIG. 15 is an enlarged view of portion E in FIG. 12.

The heating element according to an embodiment of the present disclosure may be formed in a single zone without being divided into an inner peripheral zone and an outer peripheral zone, or it may be divided into an inner peripheral zone and an outer peripheral zone. When the heating element is formed in a single zone, it is electrically connected to a pair of terminals. When the heating element is divided into an inner peripheral zone and an outer peripheral zone, the inner peripheral heating element and the outer peripheral heating element are each electrically connected to a pair of terminals. The following description is based on the case where the heating element is divided into an inner peripheral zone and an outer peripheral zone.

The heating elements 324 and 326 embedded in the ceramic plate are divided by the virtual boundary 320c into an inner peripheral zone Z1, which is the inner peripheral area inside the virtual boundary 320c, and an outer peripheral zone Z2, which is the outer peripheral area outside the virtual boundary 320c. The diameter of the virtual boundary 320c may be, for example, about 200 mm. In the inner peripheral zone Z1 of the ceramic plate 20, an inner peripheral heating element 324 is embedded, while in the outer peripheral zone Z2, an outer peripheral heating element 326 is embedded. The inner and outer peripheral heating elements 324 and 326 are embedded in the plate on the same plane parallel to the wafer mounting surface.

A pair of fifth terminals 321 and a pair of sixth terminals 322 may be provided in the central portion C near the center of the circumference of the plate. The fifth terminals 321 connect a rod to the inner peripheral heating element 324 to supply current to the inner peripheral heating element 324 via the rod. The sixth terminals 322 connect a rod to the outer peripheral heating element 326 to supply current to the outer peripheral heating element 326 via the rod.

The outer peripheral heating element 326 is configured with a coiled wire, while at least a portion of the inner peripheral heating element 324 is a heating element configured with a non-coiled wire. Specifically, the outer peripheral heating element 326 may be a coiled wire formed by helically winding a bare wire with a diameter of, for example, about 0.3 to about 0.6 mm, where the winding diameter r of the coil may range from about 2.0 to about 6.0 mm. A portion of the inner peripheral heating element 324 may be a coiled wire, while the other portion may be a non-coiled wire where a bare wire is not helically wound.

The inner peripheral heating element 324 and the outer peripheral heating element 326 will be described in detail below.

The inner peripheral heating element 324 starts from one fifth terminal 321, is continuously wired in the inner peripheral zone Z1 of the plate to form a predetermined pattern such as concentric arc portions, and is then connected to the remaining fifth terminal 321. The fifth terminals 321 and the inner peripheral heating element 324 may be connected by lead wires 328 in the form of a non-coiled wire.

The inner peripheral heating element 324 includes multiple concentric arc portions 330 and 340 and sixth connecting portions 336 that connect the concentric arc portions 330 and 340. Specifically, the inner peripheral heating element 324 may form multiple concentric patterns by being folded at multiple sixth connecting portions 336. The multiple concentric patterns of the inner peripheral heating element 324 may include multiple concentric arc portions 330 and 340 that extend in the circumferential direction of the plate. In addition, the multiple concentric patterns may include multiple sixth connecting portions 336 that connect adjacent arc portions 330 and 340 among the multiple concentric arc portions 330 and 340. The adjacent arc portions 330 and 340 may be connected by sixth connecting portions 336 that extend in the radial direction.

The outer peripheral heating element 326 starts from one sixth terminal 322, is continuously wired in the outer peripheral zone Z2, which is the outer peripheral area of the plate 20 to form a certain pattern such as concentric circles, and is then connected to the remaining sixth terminal 322. During this process, the outer peripheral heating element 326 may form multiple concentric patterns by being folded at seventh connecting portions 337 in a form that surrounds the inner peripheral heating element 324. The sixth terminals 322 and the outer peripheral heating element 326 may be connected by lead wires 329 in the form of a non-coiled wire.

Specifically, the multiple concentric patterns of the outer peripheral heating element 326 may include multiple concentric arc portions 332 that extend in the circumferential direction of the plate. In addition, the multiple concentric patterns may include seventh connecting portions 337 that connect adjacent arc portions 332 among the multiple concentric arc portions 332. Multiple seventh connecting portions 337 may be formed. The adjacent arc portions 332 may be connected by the seventh connecting portions 337 extending in the radial direction. The concentric arc portions 330, 340, and 332 of the inner peripheral heating element 324 and the outer peripheral heating element 326 may respectively have different diameters with respect to the center of the plate.

The concentric arc portions 330 and 340 include concentric arc portions 330 configured with a coiled wire and concentric arc portions 340 configured with a non-coiled wire. In this case, the concentric arc portions 340 of the inner peripheral heating element 324, which are located in the area where thermal overlap occurs, may be configured with a non-coiled wire. The concentric arc portions 330 and 340 include the arc portion closest to the center of the plate (first arc portion) and the arc portion farthest from the center of the plate (second arc portion). At least one arc portion 340 between the first arc portion and the second arc portion may be configured with a non-coiled wire. Among the arc portions between the first arc portion and the second arc portion, the remaining arc portions 330, except for the non-coiled wire arc portions, may be configured with a coiled wire. In addition, the first arc portion and the second arc portion may also be configured with a coiled wire.

The sixth connecting portions 336 connecting adjacent concentric arc portions 340 of non-coiled wires may be configured with either a non-coiled wire or a coiled wire. Preferably, to prevent a temperature drop near the connecting portions, the sixth connecting portions 336 connecting adjacent concentric arc portions 340 in the form of a wire may be configured with a coiled wire.

The first arc portion may be a portion of the inner peripheral heating element 324, and the second arc portion may be a portion of the outer peripheral heating element 326. In this case, the first arc portion is electrically connected to the fifth terminal 321, and the second arc portion is electrically connected to the sixth terminal 322.

Referring to FIG. 12, the distance between the center of the plate and the second arc portion may be divided into three equal portions: an “i” area closest to the center of the plate, an “o” area farthest from the center of the plate, and an “m” area between the “i” and “o” areas. The arc portions 340 in the form of a wire may be positioned in the middle area, the “m” area, which is the intermediate area when dividing the distance between the center of the plate and the second arc portion into three equal portions.

When concentric arc portions 330 configured with a coiled wire and concentric arc portions 340 configured with a non-coiled wire with the same wire diameter are wired in the same section, since the length of the concentric arc portions 340 configured with the non-coiled wire is shorter, the amount of generated heat is reduced compared to the concentric arc portions 330 configured with the coiled wire. Accordingly, thermal overlap may be prevented.

As illustrated in FIG. 12, when two concentric arc portions 340 were configured with a non-coiled wire made of Mo material and having a diameter of 0.5 mm, a power energy of 33.6 W was measured when the heating element length was 262.4 mm. This represents a reduction of 38.7 W in power energy compared to the use of the concentric arc portions of a conventional coiled wire (which exhibited a power energy of 72.3 W when the coiled wire was made of Mo material and had a wire diameter of 0.5 mm, a coil winding diameter of 3 mm, and a bare wire length of 594.5 mm forming the coil), which corresponds to an about 53.5% reduction in power energy.

In addition, when using the concentric arc portions 340 configured with a non-coiled wire, the adjacent patterns are spaced farther apart from each other and a margin exists in the interval P2. Therefore, there is an advantage in terms of pattern design and manufacturing process compared to when using the arc portions 330 configured with a coiled wire. FIGS. 14A and 14B are views comparing the concentric arc portions 330 configured with a coiled wire (FIG. 14A) and the concentric arc portions 340 configured with a non-coiled wire (FIG. 14B) where the coiled wire and the non-coiled wire were formed using bare wires of the same diameter d3. In the case of the coiled wire where the bare wire is helically wound, the coil winding diameter r is larger than the wire diameter d3 of the bare wire. Thus, there is no margin in the interval P1 between patterns.

In an embodiment of the present disclosure, the inner peripheral heating element 324 and the outer peripheral heating element 326 may be formed using bare wires of the same diameter, or the inner peripheral heating element 324 may partially have different diameters. For example, the wire diameters of the bare wires used in the non-coiled wire arc portions 340 and the coiled wire arc portions 330 may be made different. The resistance value may be changed by changing the wire diameter of the bare wires used in the non-coiled wire arc portions 340. In addition, the non-coiled wire arc portions 340 may be made of a high-resistance alloy material such as MoW, while the remaining arc portions 330 may be made of Mo material to increase the amount of generated heat.

When the wire diameters or materials of the non-coiled wire arc portions 340 and the coiled wire arc portions 330 are different, the non-coiled wire arc portions 340 and the coiled wire arc portions 330 may be electrically connected by a conductive connecting member 350. Without using the connecting member 350, the non-coiled wire arc portions 340 and the coiled wire arc portions 330 may be configured as a single wire, and the connecting portion between the non-coiled wire arc portions 340 and the coiled wire arc portions 330 may be configured to have a tapering shape. Alternatively, the connecting portion between the non-coiled wire arc portions 340 and the coiled wire arc portions 330 may be joined using welding or the like.

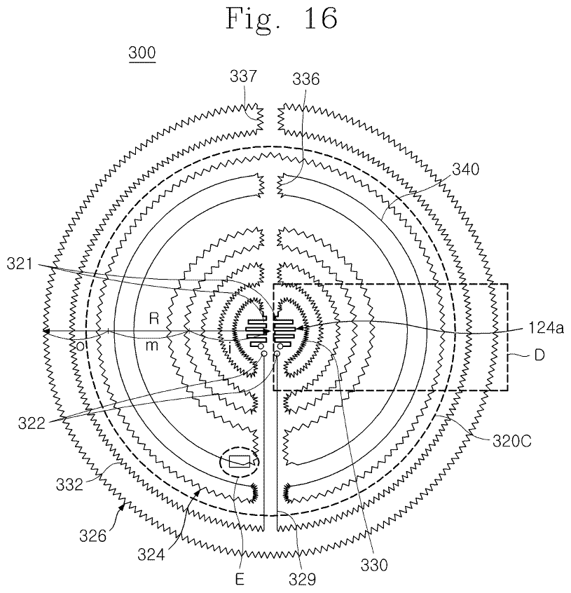

FIG. 16 is a view illustrating a modification of the heating element shape illustrated in FIG. 12.

The embodiment of the present disclosure illustrated in FIG. 16 is an embodiment in which the first inner peripheral heating element 124a illustrated in FIG. 3 is additionally provided in the heating element of FIG. 12. That is, the first inner peripheral heating element 124a of a non-coiled heating pattern is additionally provided in the central portion C of the circumference in FIG. 12. The description of the first inner peripheral heating element 124a in FIG. 16 may be replaced with the description provided for FIG. 3.

In the above description, a ceramic plate divided into an inner peripheral zone Z1 and an outer peripheral zone Z2 has been described as an example. However, the embodiments of the present disclosure are not limited thereto. That is, the heating element may be provided in a single zone without dividing the plate into multiple zones, or the present disclosure may also be applied to a multi-zone heater in which the plate is divided into three or more fan-shaped areas at predetermined angles and heating elements correspond to the respective divided areas.

In the foregoing, the present disclosure has been described based on specific details, such as concrete components, limited embodiments, and drawings, but these have been provided merely to aid a more comprehensive understanding of the present disclosure, and the present disclosure is not limited to the above-described embodiments. Various modifications and alterations may be made without departing from the essential characteristics of the present disclosure by a person ordinarily skilled in the art to which the present disclosure pertains. Therefore, the spirit of the present disclosure should not be limited to the described embodiments, and not only the appended claims, but also all technical ideas that are equivalent or have equivalent modifications to the claims should be construed as being included within the scope of the present disclosure. The above-described individual embodiments may be combined and utilized together as needed.

What is claimed is:

1. A ceramic heater comprising:
a plate;
a heating element embedded in the plate; and
a cylindrical shaft having an internal space,
wherein a portion of the heating element is a coiled wire, and another portion of the heating element is a non-coiled wire,
wherein the heating element comprises an inner peripheral heating element located in an inner peripheral area of the plate,
wherein at least a portion of the inner peripheral heating element is arranged in the central portion of the plate, and the inner peripheral heating element arranged in the central portion is the non-coiled wire,
wherein the plate comprises a first surface and a second surface,
wherein the shaft is connected to the second surface of the plate,
wherein the central portion of the plate corresponds to the internal space of the shaft,
wherein the inner peripheral heating element of the non-coiled wire is arranged in the central portion of the plate corresponding to the internal space of the shaft, and
wherein the inner peripheral heating element arranged in the central portion of the plate and the inner peripheral heating element arranged outside the central portion of the plate have different wire diameters or materials.

2. The ceramic heater of claim 1, wherein the heating element further comprises an outer peripheral heating element located in an outer peripheral area of the plate.

3. A ceramic heater comprising:
a plate; and
a heating element embedded in the plate,
wherein the heating element comprises multiple concentric arc portions and multiple connecting portions connecting the concentric arc portions,
wherein the concentric arc portions comprise a first arc portion closest to a center of the plate and a second arc portion farthest from the center of the plate,
wherein at least one arc portion between the first arc portion and the second arc portion is a non-coiled wire, and
wherein an arc portion, other than the non-coiled wire arc portion, between the first arc portion and the second arc portion is a coiled wire.

4. The ceramic heater of claim 3, wherein, when a distance between the second arc portion and the center of the plate is divided into three equal portions, the non-coiled wire arc portion is located in a middle area of the distance divided into the three equal portions.

5. The ceramic heater of claim 3, wherein the heating element is electrically connected to a pair of first terminals.

6. The ceramic heater of claim 3, wherein the first arc portion is electrically connected to a pair of first terminals, and
wherein the second arc portion is electrically connected to a pair of second terminals.

7. The ceramic heater of claim 3, wherein the non-coiled wire and the coiled wire have different wire diameters or materials.

8. The ceramic heater of claim 7, wherein the non-coiled wire and the coiled wire are connected by a conductive connecting member.

9. The ceramic heater of claim 3, wherein the heating element comprises an outer peripheral heating element located in an outer peripheral area of the plate and an inner peripheral heating element located in an inner peripheral area of the plate.

10. The ceramic heater of claim 3, wherein the heating element further comprises a non-coiled heating pattern arranged in the central portion of the plate.
